(19) United States
(12) Patent Application Publication
(10) Pub. No.: US 2021/0054507 A1
(43) Pub. Date: Feb. 25, 2021

(54) APPARATUS FOR TREATING SUBSTRATE

(71) Applicant: SEMES CO., LTD., Chungcheongnam-do (KR)

(72) Inventors: Seunghan LEE, Chungcheongnam-do (KR); Jongsu CHOI, Chungcheongnam-do (KR); Jong Seok SEO, Chungcheongnam-do (KR); Junho SEO, Seoul (KR); Younghun JUNG, Chungcheongnam-do (KR); Kyungjin SEO, Chungcheongnam-do (KR); Jung-Hyun LEE, Chungcheongnam-do (KR); Moon Hyung BAE, Daegu (KR); Sang Jin BAE, Daejeon (KR)

(21) Appl. No.: 16/997,491

(22) Filed: Aug. 19, 2020

(30) Foreign Application Priority Data
Aug. 19, 2019 (KR) 10-2019-0100915

(51) Int. Cl. C23C 16/455; H01L 21/67; C23C 16/44

(52) U.S. Cl. CPC C23C 16/45565; C23C 16/4412; H01L 21/67098; H01L 21/67017

(57) ABSTRACT

An embodiment of the inventive concept provides an apparatus for treating a substrate. The apparatus for treating a substrate includes a chamber having a treating space inside the chamber and a gas inlet unit entering a gas into the treating space. The gas inlet unit includes an introduction pipe through which the gas is entered, and a discharging plate in which a discharging hole discharging the gas entered through the introduction pipe is formed. The discharging hole is arranged such that density for each area of the discharging plate is different.

### CROSS-REFERENCE TO RELATED APPLICATIONS

A claim for priority under 35 U.S.C. § 119 is made to Korean Patent Application No. 10-2019-0100915 filed on Aug. 19, 2019, in the Korean Intellectual Property Office, the entire contents of which are hereby incorporated by reference.

### BACKGROUND

Embodiments of the inventive concept described herein relate to an apparatus for treating a substrate.

Various processes such as cleaning, deposition, photographing, etching, ion implantation, and the like are performed to manufacture a semiconductor device. Deposition and coating processes are used, as a process of forming a film on a substrate, among these processes. Generally, the deposition process is a process of depositing a process gas on a substrate to form a film, and the coating process is a process of applying a treatment solution to a substrate to form a liquid film.

Before and after a film is formed on a substrate, a process of baking the substrate is performed. The baking process is a process of heating a substrate at a process temperature or higher in an enclosed space, and heats the entire area of the substrate at a uniform temperature or adjusts the temperature for each area of the substrate depending on an operator.

FIG. 1 is a perspective view of a cross section illustrating a general bake treatment apparatus. Referring to FIG. 1, a plurality of introduction pipes 2 are positioned on the upper surface of the bake treatment apparatus, and outside air is entered into a buffer space 4 through the introduction pipes 2. The outside air entered into the buffer space 4 needs to be supplied to the substrate through discharging holes 8 of a discharging plate 6.

However, the flow rate or volume of the outside air depends on locations of the discharging holes 8. Accordingly, the non-uniform volume of a gas is supplied to each region of the substrate, which makes it difficult to uniformly control the temperature of each region of the substrate.

### SUMMARY

Embodiments of the inventive concept provide an apparatus capable of uniformly supplying a gas for each area.

An embodiment of the inventive concept provides an apparatus for treating a substrate.

According to an exemplary embodiment, the apparatus for treating a substrate includes a chamber having a treating space inside the chamber and a gas inlet unit entering a gas into the treating space. The gas inlet unit includes an introduction pipe through which the gas is entered, and a discharging plate in which a discharging hole discharging the gas entered through the introduction pipe is formed. The discharging hole is arranged such that density for each area of the discharging plate is different.

The discharging hole may be arranged in a central area more densely than an edge area of the discharging plate. The apparatus further includes an exhaust unit having an exhaust flow path for exhausting the gas supplied to the treating space. The exhaust flow path may be provided to have a shape surrounding the discharging plate.

The gas inlet unit may further include a distribution plate, which is positioned between the introduction pipe and the discharging plate, and in which a distribution hole where the gas is distributed is formed. The discharging hole may be provided such that the number of the discharging hole is greater than the number of the distribution hole.

The discharging hole may have a diameter greater than the distribution hole.

The introduction pipe, the distribution plate, and the discharging plate may be positioned sequentially from top to bottom. When viewed from above a top, the discharging hole and the distribution hole may be arranged alternately. A virtual line connecting the adjacent discharging hole along a radial direction of the discharging plate may be provided in a streamlined shape.

According to an exemplary embodiment, an apparatus for treating a substrate includes a chamber having a treating space inside the chamber and a gas inlet unit entering a gas into the treating space. The gas inlet unit includes an introduction pipe through which the gas is entered, a discharging plate in which a plurality of discharging holes discharging the gas entered through the introduction pipe are formed, and a distribution plate, which is positioned between the introduction pipe and the discharging plate, and in which a plurality of distribution holes where the gas is distributed are formed. The discharging holes are provided such that the number of the discharging holes is greater than the number of the distribution holes.

The discharging holes may be provided to have diameters greater than the distribution holes. The introduction pipe, the distribution plate, and the discharging plate may be positioned sequentially from top to bottom. When viewed from above a top, the discharging holes and the distribution holes may be arranged alternately.

The discharging holes may be arranged such that density for each area of the discharging plate is different. The apparatus further includes an exhaust unit having an exhaust flow path for exhausting the gas supplied to the treating space. The exhaust flow path may be provided to have a shape surrounding the discharging plate. The discharging holes may be arranged in a central area more densely than an edge area of the discharging plate.

A virtual line connecting the discharging holes adjacent to one another along a radial direction of the discharging plate may be provided in a streamlined shape.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a perspective view of a cross section illustrating a general bake treatment apparatus;

FIG. 2 is a perspective view schematically illustrating a substrate treating apparatus according to an embodiment of the inventive concept;

FIG. 3 is a cross-sectional view of a substrate treating apparatus illustrating a coating block or developing block of FIG. 2;

FIG. 4 is a plan view of the substrate treating apparatus of FIG. 3;

FIG. 5 is a view illustrating an example of a hand of the transfer robot of FIG. 4;

FIG. 6 is a plan view schematically illustrating an example of the heat treatment chamber of FIG. 5;

FIG. 7 is a front view of the heat treatment chamber of FIG. 6;

FIG. 8 is a cross-sectional view illustrating the heating unit of FIG. 6;

FIG. 9 is a perspective view of a cross section illustrating the enlarged gas inlet unit of FIG. 7;

FIG. 10 is a plan view of a discharging plate illustrating an arrangement structure of the discharging holes of FIG. 9;

FIG. 11 is a view illustrating a comparison of sizes between the inlet port, distribution hole, and discharging hole of FIG. 9; and

FIG. 12 is a cross-sectional view illustrating the liquid treatment chamber of FIG. 4.

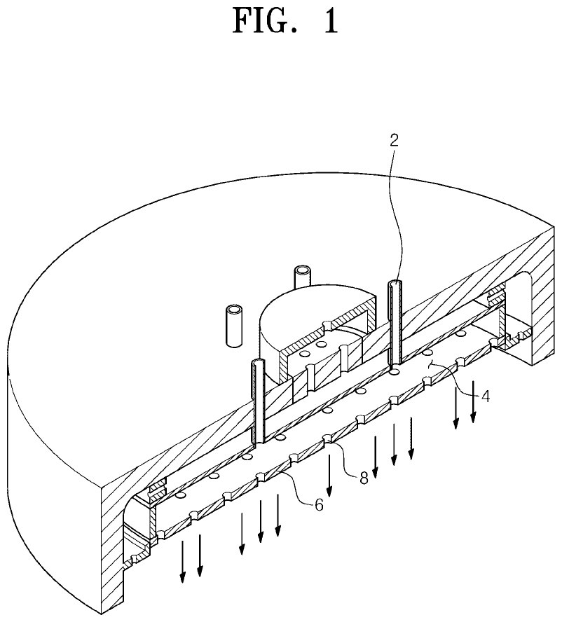

### DETAILED DESCRIPTION

Hereinafter, embodiments of the inventive concept will be described in detail with reference to the accompanying drawings. The inventive concept may, however, be embodied in different forms and should not be constructed as limited to the embodiments set forth herein. Rather, these embodiments are provided so that this disclosure will be thorough and complete, and will fully convey the scope of the inventive concept to those skilled in the art. Accordingly, in the drawings, the dimensions of components are exaggerated for clarity of illustration.

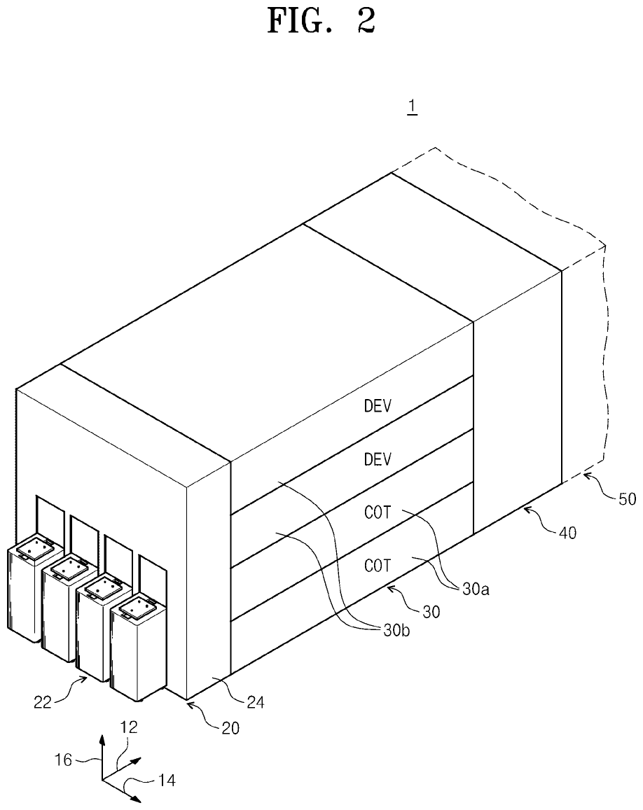

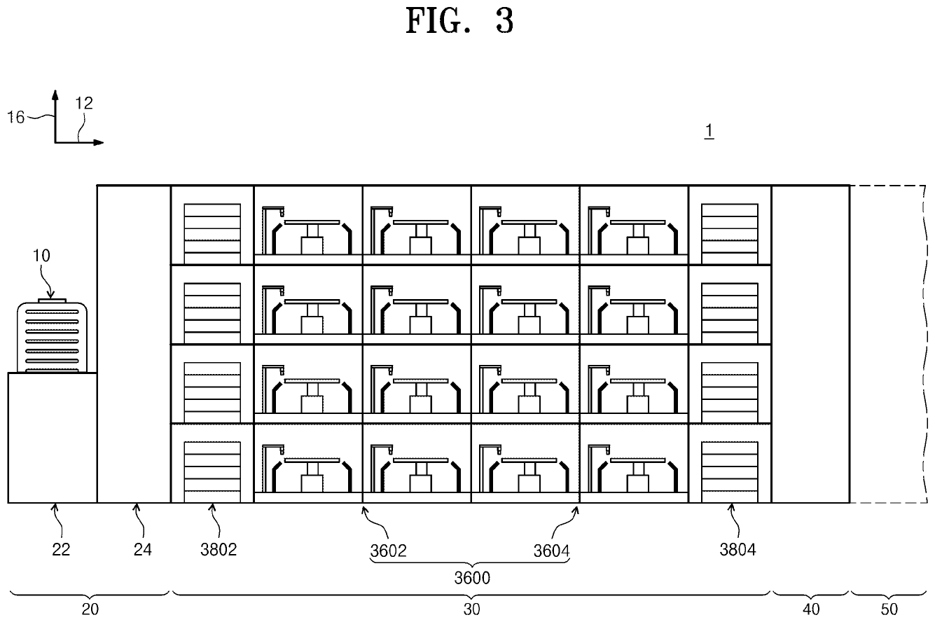

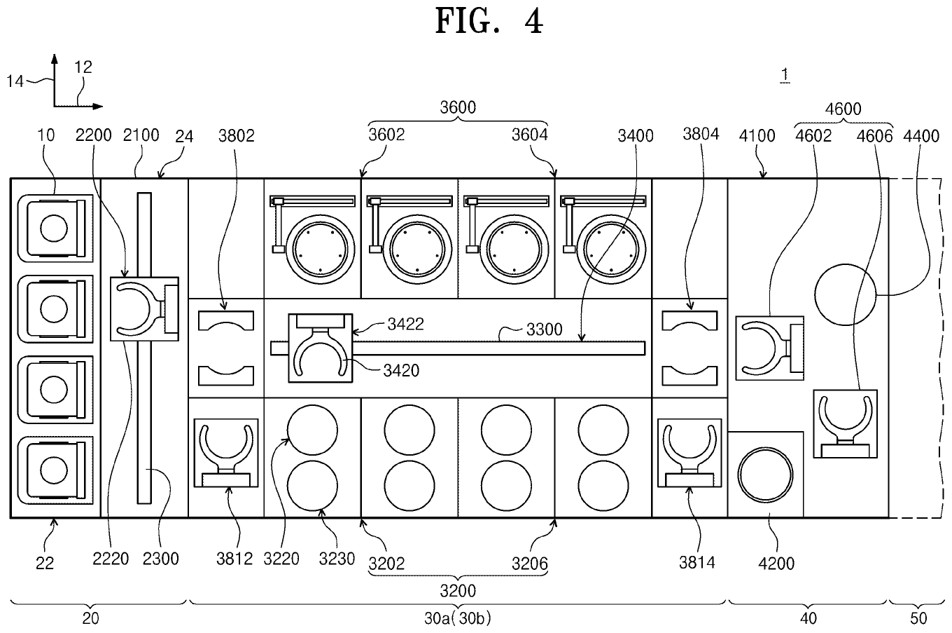

FIG. 2 is a perspective view schematically illustrating a substrate treating apparatus according to an embodiment of the inventive concept. FIG. 3 is a cross-sectional view of a substrate treating apparatus illustrating a coating block or developing block of FIG. 2. FIG. 4 is a plan view of the substrate treating apparatus of FIG. 3. Referring to FIGS. 2 to 4, a substrate treating apparatus 1 includes an index module 20, a treating module 30, and an interface module 40. According to an embodiment, the index module 20, the treating module 30, and the interface module 40 are sequentially arranged in a row. Hereinafter, a direction where the index module 20, the treating module 30, and the interface module 40 are arranged may be referred to as a “first direction” 12; when viewed from above the top, a direction perpendicular to the first direction 12 may be referred to as a “second direction” 14; and a direction perpendicular to both the first direction 12 and the second direction 14 may be referred to as a “third direction 16”.

The index module 20 transfers a substrate W from a container 10 where the substrate W is accommodated, to the treating module 30, and accommodates the completely-treated substrate W into the container 10. The length direction of the index module 20 is provided as the second direction 14. The index module 20 has a load port 22 and an index frame 24. The load port 22 is located on the opposite side of the treating module 30, based on the index frame 24. The container 10 where the substrates ‘W’ are accommodated is placed at the load port 22. The plurality of load ports 22 may be provided, and the plurality of load ports 22 may be disposed along the second direction 14.

The sealing container 10 such as a front open unified pod (FOUP) may be used as the container 10. The container 10 may be placed at the load port 22, by a transfer means (not shown) such as overhead transfer, overhead conveyor, or automatic guided vehicle or by an operator.

An index robot 2200 is provided inside the index frame 24. A guide rail 2300 of which the length direction is provided as the second direction 14 may be provided in the index frame 24; the index robot 2200 may be provided to be movable on the guide rail 2300. The index robot 2200 may include a hand 2220 on which the substrate W is placed, and the hand 2220 may be provided to move forward and backward, to rotate about the third direction 16, and to move along the third direction 16.

The treating module 30 performs a coating process and a developing process on the substrate W. The treating module 30 has a coating block 30a and a developing block 30b. The coating block 30a performs a coating process on the substrate W, and the developing block 30b performs a developing process on the substrate W. The plurality of coating blocks 30a are provided, and are provided to be stacked with each other. The plurality of developing blocks 30b are provided, and are provided to be stacked with each other. According to an embodiment of the inventive concept, the two coating blocks 30a are provided, and the two developing blocks 30b are provided. The coating blocks 30a may be disposed under the developing blocks 30b. According to an example, the two coating blocks 30a perform the same process with each other, and may be provided with the same structure. Furthermore, the two developing blocks 30b perform the same process with each other, and may be provided with the same structure.

The coating block 30a has a heat treatment chamber 3200, a transfer chamber 3400, a liquid treatment chamber 3600, and a buffer chamber 3800. The heat treatment chamber 3200 performs a heat treatment process on the substrate W. The heat treatment process may include a cooling process and a heating process. The liquid treatment chamber 3600 forms a liquid film by supplying liquid on the substrate W. The liquid film may be a photoresist film or an anti-reflection film. The transfer chamber 3400 transfers the substrate W between the heat treatment chamber 3200 and the liquid treatment chamber 3600 within the coating block 30a.

The transfer chamber 3400 is provided such that the length direction of the transfer chamber 3400 is parallel to the first direction 12. The transfer robot 3422 is provided in the transfer chamber 3400. The transfer robot 3422 transfers a substrate between the heat treatment chamber 3200, the liquid treatment chamber 3600, and the buffer chamber 3800. According to an embodiment, the transfer robot 3422 may have a hand 3420 on which the substrate W is placed, and the hand 3420 may be provided to move forward and backward, to rotate about the third direction 16, and to move in the third direction 16. The guide rail 3300 of which the length direction is provided to be parallel to the first direction 12 may be provided in the transfer chamber 3400; the transfer robot 3422 may be provided to be movable on the guide rail 3300.

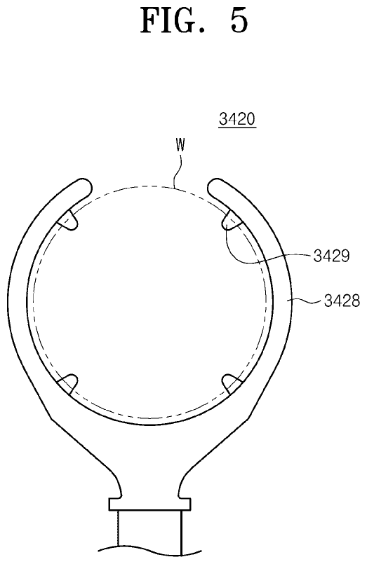

FIG. 5 is a view illustrating an example of a hand of the transfer robot of FIG. 4. Referring to FIG. 5, the hand 3420 has a base 3428 and a support protrusion 3429. The base 3428 may have an annular ring shape in which a part of the circumference is cut. The base 3428 has an inner diameter greater than the diameter of the substrate W. The support protrusion 3429 extends inwardly from the base 3428. The plurality of support protrusions 3429 are provided, and support the edge area of the substrate W. According to an embodiment, four support protrusions 3429 may be provided at equal intervals.

The plurality of heat treatment chambers 3200 are provided. The heat treatment chambers 3200 are arranged along the first direction 12. The heat treatment chambers 3202 are located on one side of the transfer chamber 3400. The heat treatment chamber 3202 located to be closest to the index module 20 among the heat treatment chambers 3200 performs heat treatment on a substrate before the substrate is transferred to the liquid treatment chamber 3600; the other heat treatment chamber 3206 performs heat treatment on the substrate treated in the liquid treatment chamber 3600. In this embodiment, a heat treatment chamber located to be closest to the index module 20 is defined as the front heat treatment chamber 3202.

This embodiment is exemplified with the rear heat treatment chamber 3204 among the plurality of heat treatment chambers 3200. The rear heat treatment chamber 3204 performs bake treatment on the film applied on the substrate W to cure the film. The rear heat treatment chamber 3204 exhausts volatile substances generated from the coating film by supplying outside air to a space where the substrate W is treated. Optionally, a process gas may be supplied to the space where the substrate W is treated. According to an embodiment, the process gas may be a hexamethyldisilane gas. The process gas may be supplied before the coating film is formed on the substrate W.

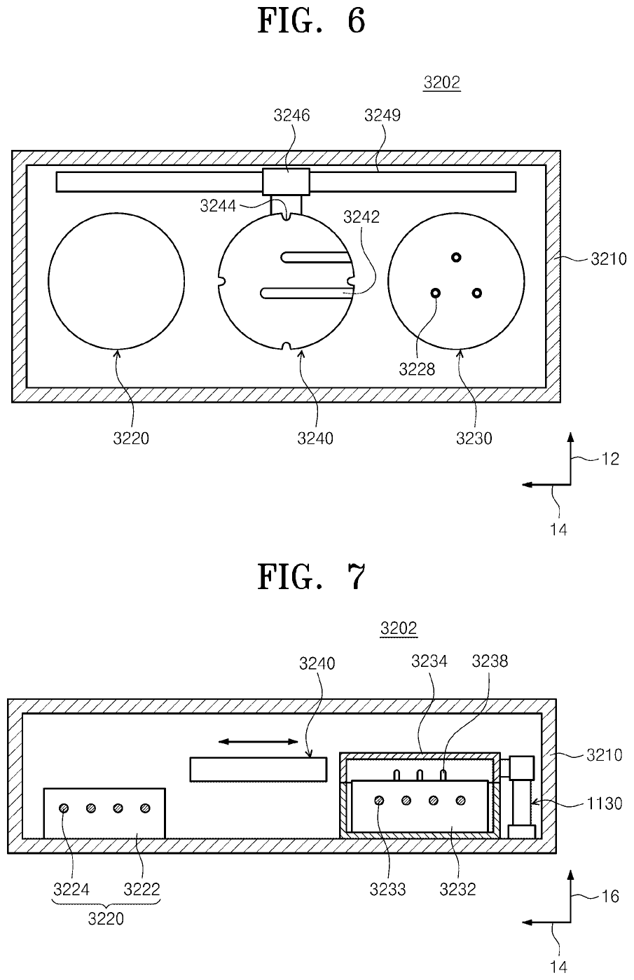

FIG. 6 is a plan view schematically illustrating an example of the heat treatment chamber of FIG. 5. FIG. 7 is a front view of the heat treatment chamber of FIG. 6. Referring to FIGS. 6 and 7, the heat treatment chamber 3202 has housing 3210, a cooling unit 3220, a heating unit 3230, and a transfer plate 3240.

The housing 3210 is provided in the shape of a generally rectangular parallelepiped. An open hole (not shown) through which the substrate W enters and exits is formed on the side wall of the housing 3210. The open hole may be maintained in an opened state. Optionally, a door (not shown) may be provided to open and close the open hole. The cooling unit 3220, the heating unit 3230, and the transfer plate 3240 are provided in the housing 3210. The cooling unit 3220 and the heating unit 3230 are provided side by side along the second direction 14. According to an embodiment, the cooling unit 3220 may be located to be closer to the transfer chamber 3400 than the heating unit 3230.

The cooling unit 3220 has a cooling plate 3222. When viewed from above the top, the cooling plate 3222 may have a generally circular shape. A cooling member 3224 is provided on the cooling plate 3222. According to an embodiment, the cooling member 3224 may be formed inside the cooling plate 3222, and may be provided as a flow path through which a cooling fluid flows.

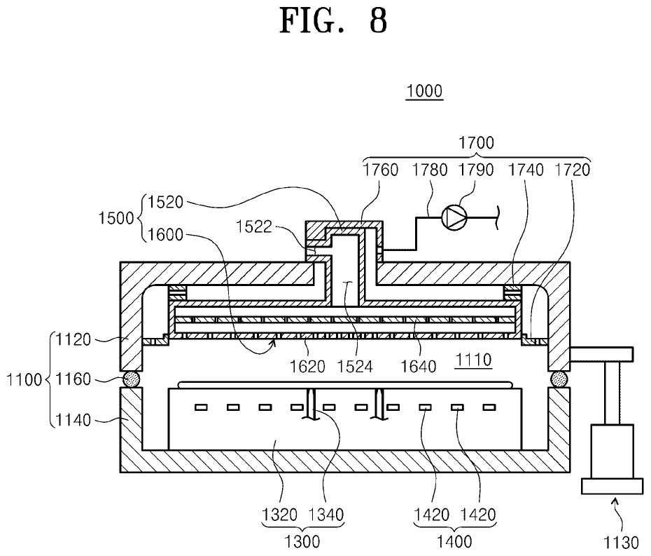

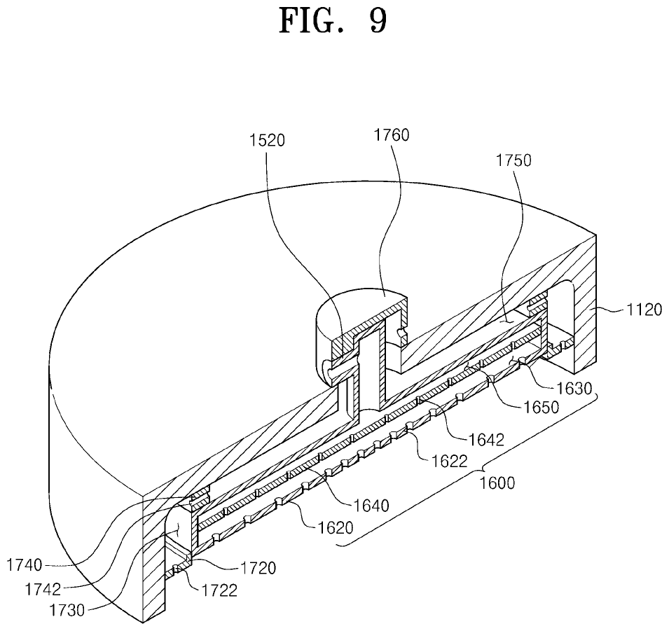

The heating unit 3230 is provided as an apparatus 1000 for heating a substrate at a temperature higher than a room temperature. The heating unit 1000 performs heat treatment on the substrate ‘W’ in a state of normal pressure or less. FIG. 8 is a cross-sectional view illustrating the heating unit of FIG. 6. FIG. 9 is a perspective view of a cross section illustrating the enlarged gas inlet unit of FIG. 7. Referring to FIGS. 8 and 9, the heating unit 1000 includes housing 1100, a substrate support unit 1300, a heater unit 1400, a gas inlet unit 1500, and an exhaust unit.

The housing 1100 provides a treating space 1110 for heating the substrate W therein. The treating space 1110 is provided as a space blocked from the outside. The housing 1100 includes an upper body 1120, a lower body 1140, and a sealing member 1160.

The upper body 1120 is provided in a cylindrical shape of which a lower portion is opened. For example, the upper body 1120 may have a cylindrical shape. An opening is formed on the upper surface of the upper body 1120. The opening may be formed in an area corresponding to the central axis of the upper body 1120.

The lower body 1140 is provided in a cylindrical shape of which an upper portion is opened. For example, the lower body 1140 may have a cylindrical shape. The lower body 1140 is located under the upper body 1120. The upper body 1120 and the lower body 1140 are positioned to face each other in the vertical direction. The upper body 1120 and the lower body 1140 are combined with each other to form a treating space 1110 therein. The upper body 1120 and the lower body 1140 are positioned such that the central axes thereof are the same as each other in the vertical direction. The lower body 1140 may have the same diameter as the upper body 1120. That is, the upper end of the lower body 1140 may be positioned to face the lower end of the upper body 1120.

One of the upper body 1120 and the lower body 1140 is moved to an open location or blocked location by a lifting member 1130, and the other is fixed at the location thereof. According to an example, the location of the lower body 1140 may be fixed, and the upper body 1120 may be moved between the open location and the blocked location by the lifting member 1130. Here, the open location is a location where the upper body 1120 and the lower body 1140 are spaced from each other to open the treating space 1110. The blocked location is a location where the treating space 1110 is sealed from the outside by the lower body 1140 and the upper body 1120.

The sealing member 1160 seals a gap between the upper body 1120 and the lower body 1140. The sealing member 1160 is located between the lower end of the upper body 1120 and the upper end of the lower body 1140. The sealing member 1160 may be an O-ring member 1160 having an annular ring shape. The sealing member 1160 may be fixedly coupled to the upper end of the lower body 1140.

A substrate support unit 1300 supports the substrate W in the treating space 1110. The substrate support unit 1300 is fixedly coupled to the lower body 1140. The substrate support unit 1300 includes a seating plate 1320 and a lift pin 1340. The seating plate 1320 supports the substrate W in the treating space 1110. The seating plate 1320 is provided in a circular plate shape. The substrate W may be seated on the upper surface of the seating plate 1320. The area including the center in the upper surface of the seating plate 1320 functions as a seating surface on which the substrate W is seated. A plurality of pin holes 1322 are formed on the seating surface of the seating plate 1320. When viewed from above the top, the pin holes 1322 are arranged to surround the center of the seating surface. Each of the pin holes 1322 is arranged to be spaced from one another along the circumferential direction. The pin holes 1322 are located to be spaced from one another at equal intervals. A lift pin 1340 is provided in each of the pin holes 1322. The lift pin 1340 is provided to move in the vertical direction. The lift pin 1340 lifts the substrate W from the seating plate 1320 or seats the substrate ‘W’ on the seating plate 1320. For example, three pin holes 1322 may be provided.

The heater unit 1400 performs heat treatment on the substrate W placed on the seating plate 1320. The heater unit 1400 is located inside the seating plate 1320. The heater unit 1400 includes a plurality of heaters 1420. Each of the heaters 1420 is located inside the seating plate 1320. Each of the heaters 1420 is located on the same plane. Each of the heaters 1420 heats different areas of the seating plate 1320. When viewed from above the top, areas of the seating plate 1320 corresponding to the heaters 1420 may be provided as heating zones, respectively. The temperature of each of the heaters 1420 is independently adjustable. For example, there may be 15 heating zones. The temperature of each of the heating zones is measured by a sensor (not shown). The heater 1420 may be a thermoelectric element or a heating wire. Optionally, the heaters 1420 may be mounted on the bottom surface of the seating plate 1320.

The gas inlet unit 1500 enters external gas (hereinafter, outside air) into the treating space 1110. The gas inlet unit 1500 includes an introduction pipe 1520 and a discharging unit 1600. The introduction pipe 1520 is located to be inserted into the opening of the upper body 1120. That is, the introduction pipe 1520 is located in the central area of the upper surface of the upper body 1120. An inlet 1522 is formed on one side of the introduction pipe 1520, and the lower end of the introduction pipe 1520 functions as an outlet 1524. The inlet 1522 and the outlet 1524 are provided to face different directions from each other. The inlet 1522 may be provided to face the horizontal direction, and the outlet 1524 may be provided to face the vertical direction. When viewed from above the top, the outlet 1524 may be located to be the same as the central axis of the housing 1100. Accordingly, it is possible to prevent the outside air from moving sequentially to the inlet 1522 and the outlet 1524 in one direction, which may reduce the flow rate of the outside air. The outside air leaks to the outlet through the inlet 1522. The leaked outside air is delivered and distributed to the discharging unit 1600.

The discharging unit 1600 is located to face the substrate support unit 1300 in the treating space 1110. The discharging unit 1600 is located over the substrate support unit 1300. The discharging unit 1600 receives outside air from the introduction pipe 1520 and discharges the outside air into the treating space 1110. The discharging unit 1600 includes a discharging plate 1620 and a distribution plate 1640. The discharging plate 1620 is located under the introduction pipe 1520 in the treating space 1110, and the distribution plate 1640 is located between the discharging plate 1620 and the introduction pipe 1520. Each of the discharging plate 1620 and the distribution plate 1640 is provided in a plate shape with holes formed in the vertical direction. The holes formed in each plate are provided to extend from the top end to the bottom end of the plate. The hole formed in the discharging plate 1620 is referred to as a discharging hole 1622, and the hole formed in the distribution plate 1640 is referred to as a distribution hole 1642. The discharging plate 1620 and the distribution plate 1640 are located to be spaced from each other. The space between the introduction pipe 1520, the distribution plate 1640, and the discharging plate 1620, which are adjacent to one another, functions as a distribution space through which the outside air is distributed. For example, the space between the introduction pipe 1520 and the distribution plate 1640 functions as a primary distribution space 1650; the space between the distribution plate 1640 and the discharging plate 1620 functions as a secondary distribution space 1630.

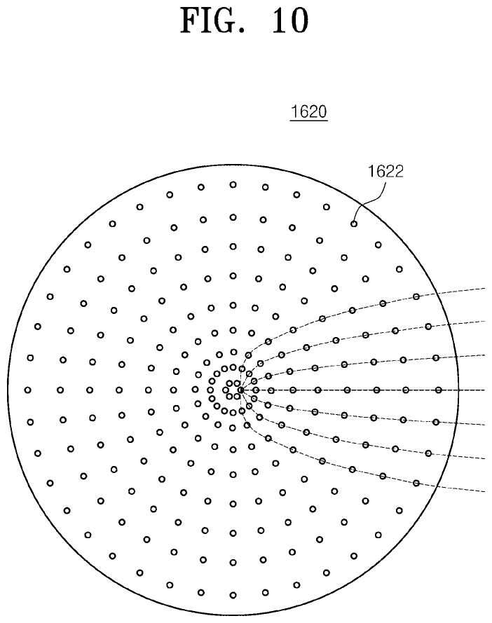

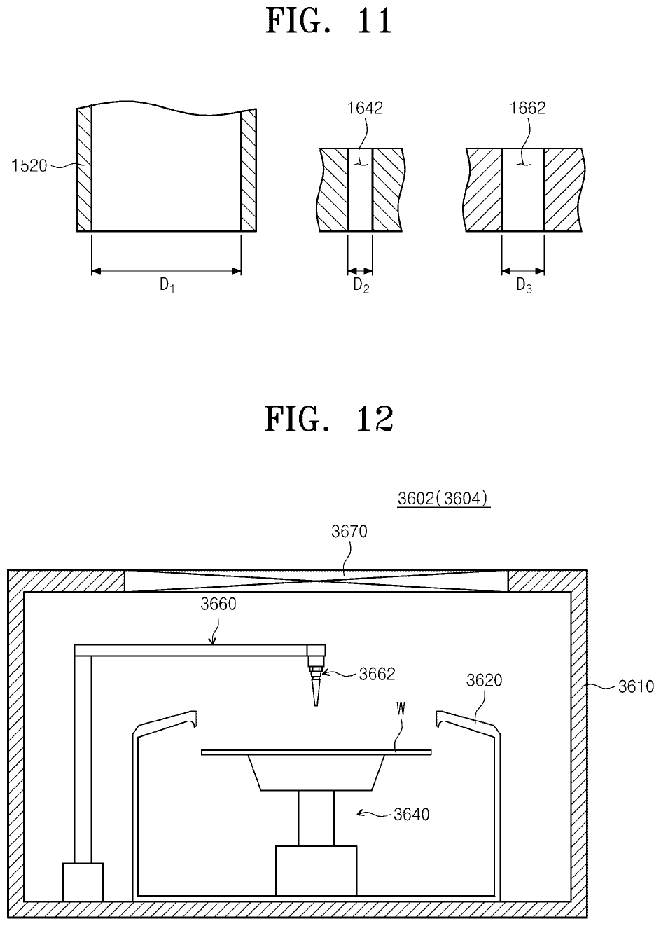

FIG. 10 is a plan view of a discharging plate illustrating an arrangement structure of the discharging holes of FIG. 9. FIG. 11 is a view illustrating a comparison of sizes between the inlet port, distribution hole, and discharging hole of FIG. 9. Referring to FIGS. 10 and 11, the discharging holes 1622 are arranged such that densities for each area of the discharging plate 1620 are different from one another. According to an example, the discharging hole 1622 is arranged in the central area more densely than the edge area of the discharging plate 1620. Accordingly, the discharging plate 1620 may discharge the large volume of outside air in the center area rather than the edge area. Even though the discharged outside air flows in the radial direction by forming an exhaust flow path 1742 outside the discharging unit 1600, this minimizes the polarization of the volume of the airflow supplied to each area of the substrate W, thereby supplying uniform outside air to the entire area of the substrate W.

Furthermore, the discharging hole 1622 is provided as a hole with a diameter greater than the distribution hole 1642, and the number of the discharging holes 1622 is provided to be greater than the number of the distribution holes 1642. The introduction pipe 1520 is provided as a hole with a diameter greater than the discharging hole 1622. As a result, the flow rate of outside air passing through the discharging hole 1622 is slower than that of outside air passing through the distribution hole 1642. For example, each outside air passing through the introduction pipe 1520, the distribution hole 1642, and the discharging hole 1622 may have a flow speed ratio of about “7,000,000:16:1”. This minimizes the influence on the film thickness applied on the substrate W, while improving the flow volume control for each area of the outside air. When viewed from above the top, the discharging hole 1622 is provided as a streamlined virtual line connecting the discharging holes 1622 adjacent to one another in the radial direction. This may minimize stains of the coating film compared to a case where the virtual line is provided as a straight line.

When viewed from above the top, the distribution hole 1642, and the discharging hole 1622 are alternately arranged. The discharging plate 1620 is provided to a blocking area of outside air passing from the distribution hole 1642. Besides, the introduction pipe 1520 and the distribution hole 1642 may be alternately arranged. For this reason, the outside air passing through the introduction pipe 1520 may hit the blocking area of the distribution plate 1640 and may be distributed primarily; the outside air passing through the distribution hole 1642 may hit the blocking area of the discharging plate 1620 and may be distributed secondarily.

The exhaust unit 1700 exhausts the atmosphere of the treating space 1110. The exhaust unit 1700 forcibly exhausts the outside air entered into the treating space 1110. The exhaust unit 1700 includes a first exhaust baffle 1720, a second exhaust baffle 1740, a cover 1760, an exhaust line 1780, and a decompression member 1790.

The first exhaust baffle 1720 is located between the discharging plate 1620 and the inner wall of the upper body 1120. The first exhaust baffle 1720 has an annular ring shape. For this reason, the space formed by the first exhaust baffle 1720, the discharging plate 1620, and the inner wall of the upper body 1120 functions as a first exhaust flow path 1730. A plurality of first exhaust holes 1722 are formed in the first exhaust baffle 1720. The first exhaust holes 1722 are provided as holes extending from the bottom surface to the top surface of the first exhaust baffle 1720. The first exhaust holes 1722 may be provided to face a vertical direction. The first exhaust holes 1722 are located to be arranged along the circumferential direction of the first exhaust baffle 1720. Each of the first exhaust holes 1722 is located at intervals the same as one another. As a result, it is possible to primarily prevent the outside air from being intensively exhausted to some areas in a process of exhausting outside air.

The second exhaust baffle 1740 is located between the discharging plate 1620 and the ceiling surface of the upper body 1120. The second exhaust baffle 1740 has an annular ring shape. For this reason, the space formed by the second exhaust baffle 1740, the discharging plate 1620, and the ceiling surface of the upper body 1120 functions as a second exhaust flow path 1750. The second exhaust baffle 1740 has a diameter equal to or smaller than the discharging plate 1620. A plurality of second exhaust holes 1742 are formed in the second exhaust baffle 1740. The second exhaust holes 1742 are provided as holes extending from the outer side surface to the inner side surface of the second exhaust baffle 1740. The second exhaust holes 1742 may be provided to face the horizontal direction. The second exhaust holes 1742 are located to be arranged in the circumferential direction of the second exhaust baffle 1740. Each of the second exhaust holes 1742 is located at intervals the same as one another. As a result, it is possible to secondarily prevent the outside air from being intensively exhausted to some areas in a process of exhausting outside air.

The cover 1760 covers the gap between the upper body 1120 and the introduction pipe 1520. The exhaust line 1780 is connected to the cover 1760. The decompression member 1790 is installed on the exhaust line 1780. The decompression member 1790 decompresses the exhaust line 1780. The exhaust power due to decompression may be delivered to the treating space 1110 through each of the exhaust flow paths 1730 and 1750, and may allow the outside air to be exhausted.

Returning to FIGS. 6 and 7, the transfer plate 3240 has a generally disc shape and has a diameter corresponding to the substrate W. A notch 3244 is formed at the edge of the transfer plate 3240. The notch 3244 may have a shape corresponding to the protrusion 3429 formed in the hand 3420 of the transfer robot 3422 described above. In addition, the notch 3244 of which the number corresponds to the number of the protrusions 3429 formed in the hand 3420 is provided, and is formed at a location corresponding to the protrusion 3429. When the top and bottom locations of the hand 3420 and the transfer plate 3240 are changed at the location where the hand 3420 and the transfer plate 3240 are aligned in the vertical direction, the transfer of the substrate W is made between the hand 3420 and the transfer plate 3240. The transfer plate 3240 is mounted on the guide rail 3249 and may be moved between the first area 3212 and the second area 3214 along the guide rail 3249 by a driver 3246 A plurality of slit-shaped guide grooves 3242 are provided in the transfer plate 3240. The guide groove 3242 extends from the end of the transfer plate 3240 to the inside of the transfer plate 3240. The length direction of the guide groove 3242 is provided along the second direction 14, and the guide grooves 3242 are located spaced from each other along the first direction 12. When the transfer of the substrate W is made between the transfer plate 3240 and the heating unit 3230, the guide groove 3242 prevents the transfer plate 3240 and the lift pin 1340 from interfering with each other.

The heating of the substrate W is made while the substrate W is placed directly on the support plate 1320; the cooling of the substrate W is made while the transfer plate 3240, on which the substrate W is placed, is in contact with the cooling plate 3222. The transfer plate 3240 is formed of a material having a high heat transfer rate such that heat is well transferred between the cooling plate 3222 and the substrate W. According to an example, the transfer plate 3240 may be formed of a metal material.

The plurality of liquid treatment chambers 3600 are provided. Some of the liquid treatment chambers 3600 may be provided to be stacked alternately. The liquid treatment chambers 3600 are placed on one side of the transfer chamber 3402. The liquid treatment chambers 3600 are arranged side by side along the first direction 12. A part of the liquid treatment chambers 3600 is provided at a location adjacent to the index module 20. Hereinafter, this liquid treatment chamber is referred to as a front liquid treatment chamber 3602. Another part of the liquid treatment chambers 3600 is provided at a location adjacent to the interface module 40. Hereinafter, this liquid treatment chamber is referred to as a rear liquid treatment chamber 3604.

The front liquid treatment chamber 3602 applies the first liquid onto the substrate W, and the rear liquid treatment chamber 3604 applies the second liquid onto the substrate W. The first liquid and the second liquid may be different types of liquids from each other. According to an embodiment, the first liquid is an anti-reflection film, and the second liquid is photoresist. The photoresist may be applied on a substrate ‘W’ on which an anti-reflection film is applied. Optionally, the first liquid may be photoresist, and the second liquid may be an anti-reflection film. In this case, the anti-reflection film may be applied on the substrate W coated with the photoresist. Optionally, the first liquid and the second liquid may be of the same type, and both the first liquid and the second liquid may be photoresist.

FIG. 12 is a diagram schematically illustrating an example of the liquid treatment chamber of FIG. 6. Referring to FIG. 12, the liquid treatment chamber 3600 has housing 3610, a treating container 3620, a substrate support unit 3640, and a liquid supply unit 3660. The housing 3610 is provided in the shape of a generally rectangular parallelepiped. An open hole (not shown) through which the substrate W enters and exits is formed on the side wall of the housing 3610. The open hole may be opened and closed by a door (not shown). A treating container 3620, a substrate support unit 3640, and a liquid supply unit 3660 are provided in the housing 3610. A fan filter unit 3670 for forming a downward airflow in the housing 3260 may be provided on the upper wall of the housing 3610. The treating container 3620 is provided in a cup shape of which the top is opened. The treating container 3620 has a treating space for treating a substrate therein. The substrate support unit 3640 is disposed inside the treating space, and supports the substrate W. The substrate support unit 3640 is provided such that the substrate W is capable of being rotated during liquid treatment. The liquid supply unit 3660 supplies liquid to the substrate W supported by the substrate support unit 3640.

The liquid supply unit 3660 includes a treatment solution nozzle 3662. The treatment solution nozzle 3662 discharges the treatment solution onto the substrate W supported by the substrate support unit 3640. For example, the treatment solution may be photoresist. The treatment solution nozzle 3662 is moved between a process location and a standby location. Herein, the process location is a location where the treatment solution nozzle 3662 faces the substrate W from the top of the substrate (W) supported by the substrate support unit 3640; the standby location is a location where the treatment solution nozzle 3662 is out of the process location. The process location may be a location where the treatment solution nozzle 3662 may discharge a treatment solution from the center of the substrate W.

Returning to FIGS. 3 and 4, the plurality of buffer chambers 3800 are provided. A part of the buffer chambers 3800 are placed between the index module 20 and the transfer chamber 3400. Hereinafter, these buffer chambers are referred to as front buffers 3802. The front buffers 3802 are provided, and are positioned to be stacked with each other along the vertical direction. Another part of the buffer chambers 3802 and 3804 is placed between the transfer chamber 3400 and the interface module 40. Hereinafter, these buffer chambers are referred to as rear buffers 3804. The rear buffers 3804 are provided, and are positioned to be stacked with each other along the vertical direction. Each of the front buffers 3802 and the rear buffers 3804 temporarily stores a plurality of substrates. The substrate W stored in the front buffer 3802 is entered or ejected by the index robot 2200 and the transfer robot 3422. The substrate W stored in the rear buffer 3804 is entered or ejected by the transfer robot 3422 and the first robot 4602.

A front transfer robot is located on one side of the front buffer 3802. The front transfer robot transfers a substrate between the front buffer 3802 and the front heat treatment chamber.

The developing block 30b has the heat treatment chamber 3200, the transfer chamber 3400, and the liquid treatment chamber 3600. The heat treatment chamber 3200 and the transfer chamber 3400 of the developing block 30b are provided with the structure and arrangement substantially similar to those of the heat treatment chamber 3200 and the transfer chamber 3400 of the coating block 30a, and thus a description thereof will be omitted.

In the developing block 30b, all the liquid treatment chambers 3600 are provided as the developing chamber 3600 for identically developing the substrate W by supplying a developer.

The interface module 40 connects the treating module 30 to an external exposure apparatus 50. The interface module 40 has an interface frame 4100, an additional process chamber 4200, an interface buffer 4400, and a transfer member 4600.

A fan filter unit forming a downward airflow therein may be provided at an upper end of the interface frame 4100. The additional process chamber 4200, the interface buffer 4400, and the transfer member 4600 are arranged inside the interface frame 4100. Before the substrate W that is completely treated by the coating block 30a is entered into the exposure apparatus 50, the additional process chamber 4200 may perform a predetermined additional process. Optionally, before the substrate W that is completely treated by the exposure apparatus 50 is entered into the developing block 30b, the additional process chamber 4200 may perform a predetermined additional process. According to an embodiment, the additional process may be an edge exposure process for exposing an edge area of the substrate W, a top surface cleaning process for cleaning the top surface of the substrate W, or a bottom surface cleaning process for cleaning the bottom surface of the substrate W. A plurality of additional process chambers 4200 are provided, and may be provided to be stacked on each other. All the additional process chambers 4200 may be provided to perform the same process. Optionally, some of the additional process chambers 4200 may be provided to perform different processes.

The interface buffer 4400 provides a space where the substrate W transferred between the coating block 30a, the additional process chamber 4200, the exposure apparatus 50, and the developing block 30b temporarily stays during transfer. A plurality of interface buffers 4400 may be provided, and a plurality of interface buffers 4400 may be provided to be stacked on each other.

According to an embodiment, the additional process chamber 4200 may be arranged on one side and the interface buffer 4400 may be arranged on the other side, based on the extension line of the length direction of the transfer chamber 3400.

The transfer member 4600 transfers the substrate W between the coating block 30a, the additional process chamber 4200, the exposure apparatus 50, and the developing block 30b. The transfer member 4600 may be provided as one or more robots. According to an embodiment, the transfer member 4600 has a first robot 4602 and a second robot 4606. The first robot 4602 may be provided to transfer the substrate W between the coating block 30a, the additional process chamber 4200, and the interface buffer 4400; the interface robot 4606 may be provided to transfer the substrate W between the interface buffer 4400 and the exposure apparatus 50; the second robot 4604 may be provided to transfer the substrate W between the interface buffer 4400 and the developing block 30b.

Each of the first robot 4602 and the second robot 4606 may include a hand on which the substrate W is placed, and the hand may be provided to move forward and backward, to rotate about an axis parallel to the third direction 16, and to move along the third direction 16.

All the hands of the index robot 2200, the first robot 4602, and the second robot 4606 may be provided in the same shape as the hand 3420 of the transfer robot 3422. Optionally, the hand of the robot that directly exchanges the substrate W with the transfer plate 3240 of the heat treatment chamber may be provided in the same shape as the hand 3420 of the transfer robot 3422; the hands of the remaining robots may be provided in a different shape.

According to an embodiment, the index robot 2200 is provided to directly exchange the substrate W with the heating unit 3230 of the front heat treatment chamber 3200 provided in the coating block 30a.

In addition, the transfer robot 3422 provided in the coating block 30a and the developing block 30b may be provided to directly exchange the substrate W with the transfer plate 3240 located in the heat treatment chamber 3200.

Next, an embodiment of a method for treating a substrate using the substrate treating apparatus 1 described above will be described.

A coating treatment process S20, an edge exposure process S40, an exposure process S60, and a development treatment process S80 are sequentially performed on the substrate W.

The coating treatment process S20 is performed by sequentially performing a heat treatment process S21 in the heat treatment chamber 3200, an anti-reflection film coating process S22 in the front liquid treatment chamber 3602, a heat treatment process S23 in the heat treatment chamber 3200, a photoresist film coating process S24 in the rear liquid treatment chamber 3604, and a heat treatment process S25 in the heat treatment chamber 3200.

Hereinafter, an example of a transfer path of the substrate W from the container 10 to the exposure apparatus 50 will be described.

The index robot 2200 ejects the substrate W from the container 10 and transfers the substrate W to the front buffer 3802. The transfer robot 3422 transfers the substrate W stored in the front buffer 3802 to the front heat treatment chamber 3200. The substrate W is transferred to the heating unit 3230 by the transfer plate 3240. When the heating process of the substrate is completed by the heating unit 3230, the transfer plate 3240 transfers a substrate to the cooling unit 3220. While the substrate W is supported, the transfer plate 3240 is in contact with the cooling unit 3220 to perform a cooling process of the substrate W. When the cooling process is completed, the transfer plate 3240 is moved to the top surface of the cooling unit 3220, and the transfer robot 3422 ejects the substrate W from the heat treatment chamber 3200 and transfers the substrate W to the front liquid treatment chamber 3602.

The front liquid treatment chamber 3602 applies an anti-reflection film on the substrate W.

The transfer robot 3422 ejects the substrate W from the front liquid treatment chamber 3602 and enters the substrate W into the heat treatment chamber 3200. The heating process and cooling process described above are sequentially performed in the heat treatment chamber 3200; when each heat treatment process is completed, the transfer robot 3422 ejects the substrate W and transfers the substrate W to the rear liquid treatment chamber 3604.

Afterward, the rear liquid treatment chamber 3604 applies a photoresist film on the substrate W.

The transfer robot 3422 ejects the substrate W from the rear liquid treatment chamber 3604 and enters the substrate W into the heat treatment chamber 3200. The heating process and cooling process described above are sequentially performed in the heat treatment chamber 3200; when each heat treatment process is completed, the transfer robot 3422 transfers the substrate W to the rear buffer 3804. The first robot 4602 of the interface module 40 ejects the substrate W from the rear buffer 3804 and transfers the substrate W to the auxiliary process chamber 4200.

An edge exposure process is performed on the substrate W in the auxiliary process chamber 4200.

Afterward, the first robot 4602 ejects the substrate W from the auxiliary process chamber 4200 and transfers the substrate W to the interface buffer 4400.

Afterward, the second robot 4606 ejects the substrate W from the interface buffer 4400 and transfers the substrate W to the exposure apparatus 50.

The development treatment process S80 is performed by sequentially performing a heat treatment process S81 in the heat treatment chamber 3200, a developing process S82 in the liquid treatment chamber 3600, and a heat treatment process S83 in the heat treatment chamber 3200.

Hereinafter, an example of a transfer path of the substrate W from the exposure apparatus 50 to the container 10 will be described.

The second robot 4606 ejects the substrate W from the exposure apparatus 50 and transfers the substrate W to the interface buffer 4400.

Afterward, the first robot 4602 ejects the substrate W from the interface buffer 4400 and transfers the substrate W to the rear buffer 3804. The transfer robot 3422 ejects the substrate W from the rear buffer 3804 and transfers the substrate W to the heat treatment chamber 3200. The heating process and cooling process of the substrate ‘W’ are sequentially performed in the heat treatment chamber 3200. When the cooling process is completed, the substrate W is transferred to the development chamber 3600 by the transfer robot 3422.

The developing process is performed in the developing chamber 3600 by supplying a developer to the substrate W.

The substrate W is ejected from the developing chamber 3600 by the transfer robot 3422 and is transferred to the heat treatment chamber 3200. The heating process and cooling process may be sequentially performed on the substrate W in the heat treatment chamber 3200. When the cooling process is completed, the substrate W is ejected from the heat treatment chamber 3200 by the transfer robot 3422 and is transferred to the front buffer 3802.

Afterward, the index robot 2200 ejects the substrate W from the front buffer 3802 and transfers the substrate W to the container 10.

The treating block of the above-described substrate treating apparatus 1 has been described as performing a coating treatment process and a developing treatment process. On the other hand, the substrate treating apparatus 1 may have only the index module 20 and the treating block 37 without an interface module. In this case, the treating block 37 performs only a coating treatment process, and the film applied on the substrate W may be a spin-on hard mask film (SOH).

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

According to an embodiment of the inventive concept, a gas is exhausted to the outside of the discharging plate, and a discharging hole is more densely arranged in a center area than an edge of the discharging plate. As a result, the gas may be uniformly supplied to each area of the substrate.

In addition, according to an embodiment of the inventive concept, the distribution plate and the discharging plate are positioned to be stacked, and the discharging holes are provided such that the number of discharging holes is greater than the number of distribution holes. As a result, the gas may be uniformly supplied to each area of the substrate by slowing down the flow rate of the gas through discharging holes.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a chamber having a treating space inside the chamber; and
a gas inlet unit configured to enter a gas into the treating space,
wherein the gas inlet unit includes:
an introduction pipe through which the gas is entered; and
a discharging plate in which a discharging hole discharging the gas entered through the introduction pipe is formed,
wherein the discharging hole is arranged such that density for each area of the discharging plate is different.

2. The apparatus of claim 1, wherein the discharging hole is arranged in a central area more densely than an edge area of the discharging plate.

3. The apparatus of claim 2, wherein the apparatus further comprises:
an exhaust unit having an exhaust flow path for exhausting the gas supplied to the treating space, and
wherein the exhaust flow path is provided to have a shape surrounding the discharging plate.

4. The apparatus of claim 2, wherein the gas inlet unit further includes:
a distribution plate, which is positioned between the introduction pipe and the discharging plate, and in which a distribution hole where the gas is distributed is formed.

5. The apparatus of claim 4, wherein the discharging hole is provided such that the number of the discharging hole is greater than the number of the distribution hole.

6. The apparatus of claim 4, wherein the discharging hole has a diameter greater than the distribution hole.

7. The apparatus of claim 4, wherein the introduction pipe, the distribution plate, and the discharging plate are positioned sequentially from top to bottom.

8. The apparatus of claim 7, wherein, when viewed from above a top, the discharging hole and the distribution hole are arranged alternately.

9. The apparatus of claim 7, wherein, when viewed from above a top, the introduction pipe and the distribution hole are arranged alternately.

10. The apparatus of claim 7, wherein a virtual line connecting the adjacent discharging hole along a radial direction of the discharging plate is provided in a streamlined shape.

11. An apparatus for treating a substrate, the apparatus comprising:
a chamber having a treating space inside the chamber; and
a gas inlet unit configured to enter a gas into the treating space,
wherein the gas inlet unit includes:
an introduction pipe through which the gas is entered;
a discharging plate in which a plurality of discharging holes discharging the gas entered through the introduction pipe are formed; and
a distribution plate, which is positioned between the introduction pipe and the discharging plate, and in which a plurality of distribution holes where the gas is distributed are formed,
wherein the discharging holes are provided such that the number of the discharging holes is greater than the number of the distribution holes.

12. The apparatus of claim 11, wherein the discharging holes and the distribution holes have different diameters from each other.

13. The apparatus of claim 12, wherein the discharging holes are provided to have diameters greater than the distribution holes.

14. The apparatus of claim 13, wherein the introduction pipe, the distribution plate, and the discharging plate are positioned sequentially from top to bottom.

15. The apparatus of claim 14, wherein, when viewed from above a top, the discharging holes and the distribution holes are arranged alternately.

16. The apparatus of claim 14, wherein, when viewed from above a top, the introduction pipe and the distribution holes are arranged alternately.

17. The apparatus of claim 11, wherein the discharging holes are arranged such that density for each area of the discharging plate is different.

18. The apparatus of claim 17, wherein the discharging holes are arranged in a central area more densely than an edge area of the discharging plate.

19. The apparatus of claim 18, wherein the apparatus further comprises:
an exhaust unit having an exhaust flow path for exhausting the gas supplied to the treating space, and
wherein the exhaust flow path is provided to have a shape surrounding the discharging plate.

20. The apparatus of claim 19, wherein a virtual line connecting the discharging holes adjacent to one another along a radial direction of the discharging plate is provided in a streamlined shape.
